(19) United States
(12) Patent Application Publication
(10) Pub. No.: US 2023/0272526 A1
(43) Pub. Date: Aug. 31, 2023

(54) SYSTEM, METHOD AND COMPOSITION FOR PRODUCING LIQUID REPELLANT MATERIALS

(71) Applicant: Soliyarn, LLC, Boston, MA (US)

(72) Inventors: Trisha L. Andrew, Hadley, MA (US); Aidan Kelliher, Cambridge, MA (US); Jonathan Cali, North Easton, MA (US); Timothy D. Monroe, Somerville, MA (US); Adrian J. Beach, Arlington, MA (US); Sayantani Nandy, Medford, MA (US)

(73) Assignee: Soliyarn, LLC, Boston, MA (US)

(21) Appl. No.: 18/030,371

(22) PCT Filed: Nov. 11, 2022
(86) PCT No.: PCT/US2022/049648

§ 371 Date: Apr. 5, 2023

Related U.S. Application Data
(60) Provisional application No. 63/278,327, filed on Nov. 11, 2021.

(51) Int. Cl. C23C 16/448; C23C 16/54

(52) U.S. Cl. CPC C23C 16/448; C23C 16/54

(57) ABSTRACT

Systems, methods, and compositions for producing liquid repellant materials include a first support configured to support a spool of flexible substrate, a second support configured to support a plurality of compressing rollers configured to apply a force to a segment of the flexible substrate that extends from the roll. The segment is located within a zone between the compressing rollers. The system, in an embodiment, has a plurality of gas directors, wherein each one of the gas directors is configured to direct a stream of gas that flows at least partially around one of the compressing rollers. The streams cause an air pressure reduction in the zone. Also, the system has a precursor supply configured to expose the substrate to a precursor (e.g., a siloxane precursor), resulting in a coated material or protected material.

### BACKGROUND

Conventional coatings that repel oils and water are composed of heavily-fluorinated or perfluorinated compounds, or compounds and polymers that contain at least 60 percent by weight fluorine as part of their chemical formula. These compounds have been found to be persistent and bioaccumulative in the environment and cause irreparable harm to aquatic life and human consumers.

While most hydrocarbon-based coatings can repel water with varying efficacy, no hydrocarbon-based coating formulation is known to repel oil stains, such as mineral oil, food oils (olive oil, butter, palm oil) and grease stains (hexane, heptane, octane).

In addition to the environmental impact of fluorinated compounds and the failure of others to obtain textiles that repel both water-based and hydrocarbon-based liquids, there is a need for methods of coating electrically conductive yarn, fibers or fabric that preserve electrical conductivity, are mechanically robust, and can withstand multiple washings.

Therefore there is a need to develop coatings that can repel water, grease, and oil while containing less than 30 weight percent fluorine, or, ideally, no fluorine component whatsoever. A prevailing need in the field also exists for improved processes to produce such yarns, fibers and fabrics that are both hydrophobic and oleophobic, including those that are compatible with electrically conductive materials.

Additionally, large-scale production of coatings by chemical vapor deposition have been limited by the need to use batch processes and/or challenges in maintaining a vacuum in continuous process chambers. Therefore, there is also a need for improved vapor deposition systems and methods for the continuous production of coated substrates.

### SUMMARY

Therefore, in one embodiment, a system comprises a first process chamber for coating a flexible substrate (such as yarn, fiber, fabric, a textile, metal foil or metalized plastic), resulting in a liquid repellant substance. In some embodiments, liquid repellant coatings are applied on the substrate under and/or over an electrically conductive substance to produce an electrically conductive material, such as an electrically conductive yarn, fiber or fabric. Depending on the embodiment, the system comprises a second process chamber for encapsulating the electrically conductive material with an encapsulating substance. Both continuous and non-continuous coatings are contemplated. Additionally, coatings may penetrate into the substrate or not depending on the properties of the coating substance and substrate, e.g., porosity and wettability.

In another embodiment, a device is provided for printing an encapsulated electrically conductive substance onto any flat or smooth substrate (e.g., plastic, paper, transparent conducting oxide or metal oxide surface, or nonwoven, prewoven or knit fabric surface), including print head(s) for coating and encapsulating a substrate, such as yarn, fiber or fabric. In some embodiments, the electrically conductive substance is completely encapsulated, and in other embodiments, the electrically conductive substance is partially encapsulated.

In some embodiments, the first process chamber comprises one or more load lock chambers at the substrate inlet and/or outlet of the first process chamber. In other embodiments, the second process chamber comprises one or more load lock chambers at the substrate inlet and/or outlet of the second process chamber. In further embodiments, the system has a series of load lock chambers having successively lower pressures are used at the process chamber inlet. In yet further embodiments, a series of load lock chambers having successively increasing pressures are used at the process chamber outlet. In another embodiment, the load lock chamber is a pressure reduction zone or space in which a pressure reduction effect is generated on the substrate during the production of the liquid repellant material.

In some embodiments, a material production system comprises a first support configured to support a spool of flexible substrate, a second support configured to support a plurality of compressing rollers configured to apply a force to a segment of the flexible substrate that extends from the roll. The compressing rollers are positioned and configured to compress the segment, which is located within a space or zone between the compressing rollers. The system also includes a plurality of gas directors, wherein each one of the gas directors is configured to direct a stream of gas that flows at least partially around one of the compressing rollers. The streams cause an air pressure reduction in the zone. In addition, the system has a precursor supply configured to expose the substrate to a precursor, resulting in a coated or protected material. In some embodiments, the material production system also comprises a co-reactant supply configured to expose the substance and the precursor to the co-reactant.

The above embodiments are exemplary only. Other embodiments as described herein are within the scope of the disclosed subject matter.

### BRIEF DESCRIPTION OF THE DRAWINGS

So that the manner in which the features of the disclosure can be understood, a detailed description may be had by reference to certain embodiments, some of which are illustrated in the accompanying drawings. It is to be noted, however, that the drawings illustrate only certain embodiments and are therefore not to be considered limiting of its scope, for the scope of the disclosed subject matter encompasses other embodiments as well. The drawings are not necessarily to scale, emphasis generally being placed upon illustrating the features of certain embodiments. In the drawings, like numerals are used to indicate like parts throughout the various views, in which:

FIG. 1 illustrates an embodiment of a system for coating a flexible substrate, such as yarn, fiber or fabric, with an electrically conductive and/or liquid repellant substance, in which a substrate is located within one or more process chambers during processing, in accordance with one or more aspects set forth herein;

FIG. 2 illustrates an embodiment of a system for coating a flexible substrate, such as yarn, fiber or fabric, with an electrically conductive and/or liquid repellant substance, in which a substrate is continuously fed into one or more process chambers during processing, in accordance with one or more aspects set forth herein;

FIG. 3A depicts a process chamber, in accordance with one or more aspects set forth herein;

FIG. 3B depicts further details of coating a substrate, in accordance with one or more aspects set forth herein;

FIG. 3C depicts a technique for coating a substrate, in accordance with one or more aspects set forth herein;

FIG. 4 depicts a cleaning chamber, in accordance with one or more aspects set forth herein;

FIGS. 5A & 5B depict embodiments of process chambers, in accordance with one or more aspects set forth herein;

FIGS. 6A & 6B illustrate embodiments of print heads for depositing electrically conductive substances and/or liquid repellant substances on a substrate, such as flat or smooth plastic, paper, transparent conducting oxide or metal oxide surface, or nonwoven, pre-woven or knit fabric surface, in which the substrate is printed or sprayed with precursors to electrically conductive substances and/or liquid repellant substances, in accordance with one or more aspects set forth herein; and

FIGS. 7A & 7B illustrate embodiments of entry and exit load lock chambers in accordance with one or more aspects set forth herein.

FIG. 8 depicts scanning electron microscope images of one embodiment of a substrate coated with a liquid repellent substance, in accordance with one or more aspects set forth herein;

FIG. 9 depicts scanning electron microscope images of one embodiment of a substrate coated with a liquid repellent substance, in accordance with one or more aspects set forth herein;

Corresponding reference characters indicate corresponding parts throughout several views. The examples set out herein illustrate several embodiments, but should not be construed as limiting in scope in any manner.

### DETAILED DESCRIPTION

The present disclosure relates to methods and processes for producing conductive, coated, protected, and/or liquid repellant materials, such as plastics, metallized plastics, metal foil, and textiles (e.g., fibers, yarns, and fabrics). In one embodiment, polysiloxane coatings are applied to substrates via vapor deposition and condensation of siloxane monomers, dimers, trimers, or other oligomers.

Advantageously, in some embodiments, methods and processes for preparing liquid repellant coatings are integrated with high-throughput processes for producing electrically conductive or liquid repellant materials, such as textiles, fibers, yarns or fabrics resulting from the methods and processes. Further details regarding electrically conductive fabrics and yarns may be found in, PCT Publication No. WO 2021194931A1 (Andrew, Baima and Beach), U.S. Patent Publication No. 2019/0230745A1 (Andrew, Zhang and Baima), published Jul. 25, 2019, and entitled “Electrically-heated fiber, fabric, or textile for heated apparel,” and U.S. Patent Publication No. 2018/0269006A1 (Andrew and Zhang), published Sep. 20, 2018, and entitled “Polymeric capacitors for energy storage devices, method of manufacture thereof and articles comprising the same,” each of which is incorporated herein in its entirety.

Generally stated, provided herein, in one embodiment, is a system for continuously producing protected and/or electrically conductive material (such as electrically conductive yarn, fiber or fabric) by processing a flexible substrate, such as raw or untreated yarn, fiber or fabric. The system comprises a first, second and an optional third process chamber, and spooling mechanisms. For instance, the first process chamber is for coating the substrate with an electrically conductive polymeric substance. The first process chamber introduces a precursor (e.g., a monomer) and an initiator that form the electrically conductive polymeric substance. And the second process chamber is for encapsulating the electrically conductive material with an encapsulating insulating substance. A first spooling mechanism stores the substrate within the first process chamber and flows the substrate through the first process chamber during the coating. A second spooling mechanism accepts the substrate such that the substrate continuously flows in the direction from the first process chamber to the second process chamber. The flow rate of the first and second spooling mechanisms are selected to allow the substrate to be coated with the electrically conductive substance and encapsulated with the encapsulating substance (e.g., a siloxane). The substrate is subsequently spooled after encapsulation to form a spool of electrically conductive, liquid repellant, coated or protected material.

In one embodiment, the first and second process chambers are combined as a single process chamber. For example, separation of the coating and the encapsulating is achieved through one or more of space or a physical barrier within the single process chamber. In another embodiment, the process chamber comprises vapor phase introduction of the precursor and the initiator. For example, the precursor and initiator begin reacting in the vapor phase and the coating is formed conformally around the substrate as a molecular layer. In such a case, the forming process as a molecular layer retains flexibility of the substrate after the coating. In different embodiments, the precursor composition may be 3,4-ethylenedioxythiophene, the electrically conductive substance composition may be p-doped poly(3,4-ethylenedioxythiophene), and the encapsulating substance composition may be an acrylate and/or a siloxane.

In another aspect, a device for printing a pattern of encapsulating and/or electrically conductive polymer onto any flat or smooth substrate (such as plastic, metal foil, metalized plastic (e.g., chip bag substrate), paper, transparent conducting oxide or metal oxide surface, or nonwoven, prewoven or knit fabric surface) includes at least one print head for heating at least one precursor and producing at least one vapor within a target zone of the print head. For instance, the vapor comprises a precursor and an initiator, and the surface is coated with a pattern of an electrically conductive substance and protected with an encapsulating substance when passing within the target zone of the print head.

In one embodiment, the at least one print head comprises a first print head for coating the surface with the electrically conductive substrate, and a second print head for encapsulating the electrically conductive substrate with an encapsulating substance. In another embodiment, the at least one print head comprises a single print head for coating the surface with the electrically conductive substance, and for encapsulating the electrically conductive substrate with an encapsulating substance. Further embodiments use heat-based and/or light-based initiation to coat with the encapsulating substance.

By way of example, the electrically conductive substance composition may comprise p-doped poly(3,4-ethylenedioxythiophene), and the encapsulating substance may comprise a poly(acrylate). In another implementation, the system includes a portable unit, and the system further includes a battery and movable material tanks for storing. In a further implementation, the system further comprises an outlet for delivering a cleaning solution to the substrate.

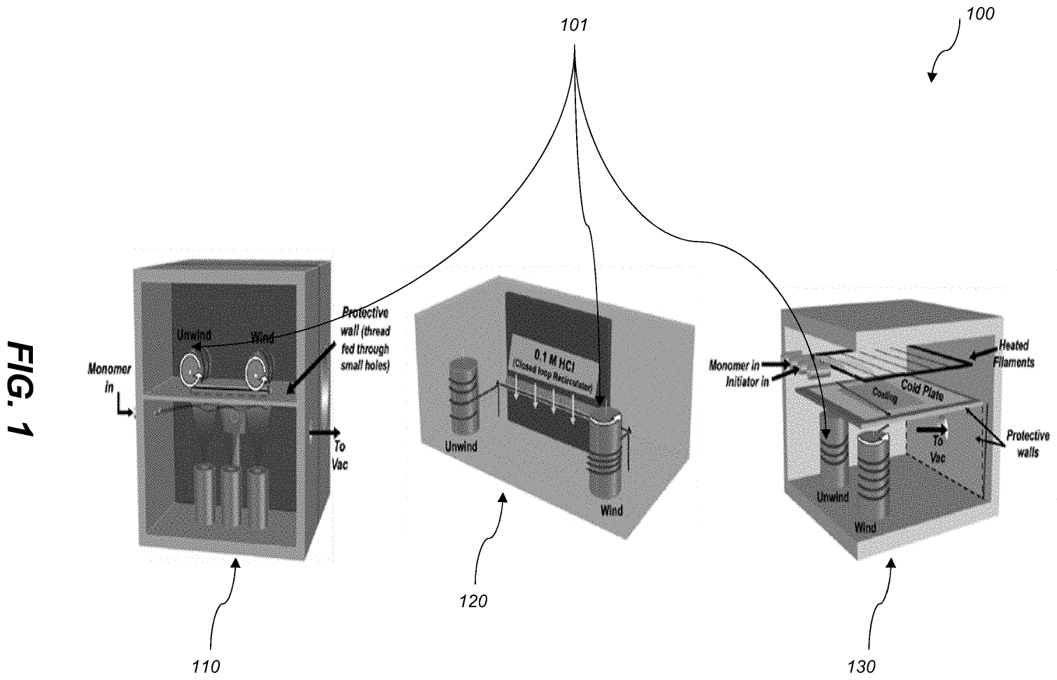

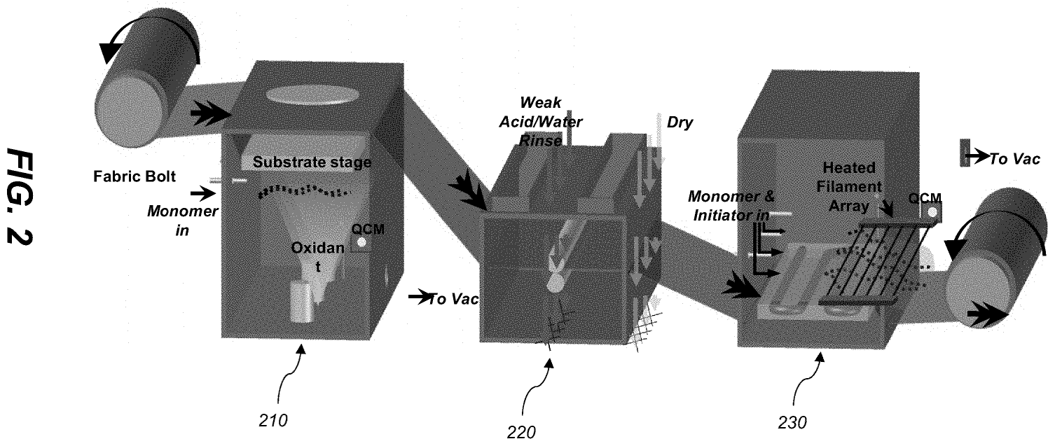

FIG. 1 illustrates a system 100 for producing electrically conductive, coated and/or protected material. According to this embodiment, the system 100 includes a coating chamber 110, an optional cleaning chamber 120, and an encapsulating chamber 130. The chambers 110, 120, and 130 can be serially linked by conveyors or other transport means or can be separately disposed. An exemplary approach to creating functional yarns in for wearable energy storage in the system embodiment of FIG. 1 is to: start with familiar and mass-produced yarns, such as cotton; deposit an electrothermally-responsive coating onto the threads of the yarns that will transform them into Joule heaters using chambers 110 and 120. This coating will not alter their characteristic feel, weight or mechanical/tensile properties. Finally, these yarns will be encapsulated with a water-repellant insulating coating using chamber 130 to create durable heaters.

In the embodiment of FIG. 1, a spool 101 of substrate is first located within the coating chamber 110. To affect an electrothermal response, a substrate is coated with the persistently p-doped conducting polymer poly(3,4-ethylenedioxythiophene), PEDOT-Cl, using a vapor deposition chamber 110 whose design was adapted from previous efforts on the in situ vapor phase polymerization of 3,4-ethylenedioxythiophene (EDOT). The major components of this chamber include: an electrical furnace to uniformly deliver FeCl₃ vapor to a sample stage situated between three to ten inches above the furnace; a heated sample stage between 5 square inches to 36 square inches; stainless steel tubing to deliver EDOT vapor from outside of the chamber; and an in situ quartz crystal microbalance (QCM) sensor to monitor the EDOT/FeCl₃ flow rates and thickness of the deposited PEDOT film in real time. Electrical heaters on the outside of the chamber near the EDOT inlets can be included to facilitate evaporation of the EDOT. Additional inert gases, such as nitrogen or argon, can be introduced into the chamber from a second gas inlet to control the process pressure and to deliver EDOT vapors. Vapor phase oligomerization and polymerization of EDOT is expected to occur in the regions where the monomer vapor flux intersects with the conical FeCl₃ vapor plume, and the resulting oligomers, which possess comparatively low kinetic energy, coats any surface placed within this region. A process pressure of 100-1000 mTorr during deposition translates into mean free paths on the order of millimeters for these reactive oligomers. Since these mean free paths are commensurate with the surface roughness of woven fabrics, the oligomers described herein are be able to sample multiple sites before finally adhering to a particular surface, yielding conformal coatings. Additionally, heating the sample stage during deposition imparts lateral mobility along the substrate surface to adsorbed oligomers, thus leading to better surface conformity and PEDOT conductivity. Stage heating also encourages oligomer-oligomer coupling to form higher molecular weight polymers.

The thickness of the growing polymer film inside the chamber is monitored in real time by a quartz crystal microbalance (QCM) sensor situated near the sample stage. The total deposition rate and film thickness values reported by the QCM sensor during vapor deposition arise from both the polymer film and unreacted EDOT/FeCl₃ being deposited onto the sensor surface. Thickest polymer films are obtained after rinsing when the EDOT and FeCl₃ flow rates are matched during deposition. Unreacted EDOT or FeCl₃ remain trapped in the films if their flow rates are mismatched, which are leached out of the film during rinsing, leading to significantly lower coating thicknesses than measured by the QCM sensor during deposition. Taking this into account, typical polymer growth rates are about 10-15 nm per minute of exposure to the reactive vapor cone, for a substrate stage temperature of 80° C.

Next, the coated substrate is moved to the cleaning chamber 120. A post deposition rinse in the cleaning chamber 120 completely removes residual FeCl₃ trapped in the vapor deposited polymer films and yields metal free, PEDOT-Cl coated substrates (e.g., yarns). The post deposition rinse contains a dilute aqueous solution, 0.001-0.1 moles per liter, of an acid, either monoprotic or diprotic, and it will further dope the PEDOT film to improve the conductivity of the resulting coated substrate (e.g., yarns and fabric comprising such yarns). After rinsing, warm air is blown through the substrate (e.g., fabric) to dry it.

Finally and still referring to FIG. 1, the cleaned, coated substrate is moved to the encapsulating chamber 130. To encapsulate the PEDOT-Cl coated substrate (e.g., yarns) with a coating, a second vapor deposition chamber 130 will be used whose design is adapted from previous efforts on the in situ radical chain polymerization of acrylate monomers. In some embodiments, liquid repellant coatings are produced by polymerization of siloxane monomers. The major components of this chamber include: a shallow, cylindrical stainless steel shell with small ports for gas flow in and out, heated filaments (typically nichrome) that can be resistively heated to 150-400° C., and a liquid-cooled stage on which the substrate is placed. For polymer film growth, an initiator and a monomer are vaporized by heat and reduced pressure. The vapors are then flowed over heated filaments to decompose the initiator into reactive radicals. The radical species and monomer condense on any substrate on the cooled stage, and the polymerization reaction occurs. Films are typically grown at pressures between 0.1-500 mTorr, and the rate of growth can be adjusted by changing the partial pressures of the initiator and monomer, chamber pressure and filament temperature. Typical polymer growth rates are 10 nm per minute of exposure to the reactive vapor. This encapsulation process is comparatively simpler and faster than the previous PEDOT-Cl coating operation and does not require a post-deposition rinse. In another embodiment, this process can also be achieved using UV light (wavelength <400 nm) in place of the wire heating filament to initiate the polymerization. For the light-initiated version, the reaction area is flooded with UV light, typically through a quartz glass window located in the ceiling of the vacuum chamber. In this case, the heated filament array is not needed, and a photoinitiator is used in place of a thermally-activated initiator.

With respect to both the coating and encapsulation steps, the coating thickness can be varied from approximately 100 to 1000 nm. Highly-uniform and conformal coatings have been formed on an array of substrate surfaces that are exposed to the reactive vapor in both chambers, without any special pre-treatment or fixing steps. Although pre-treatment (e.g., plasma treatment) and/or fixing steps are also contemplated. Further, polymer films are uniformly deposited (macroscopically) over the surface while also conformally wrapping (microscopically) the curved surface of each exposed fibril of the threads constituting the substrate. The high conformality of the conductive coating is particularly apparent in the SEM image of PEDOT-Cl coated wool gauze, where the PEDOT-Cl film contours to all the exposed surface features of the substrate with high fidelity over multiple length scales. Cross-section SEM studies have confirmed that the PEDOT and protective acrylate films are purely surface coatings and that the bulk of fibrils/threads are not swelled or dyed by the polymers. Successful vapor coatings have been carried out without any pre-treatment steps, regardless of surface chemistry, thread/yarn composition and weave density. The polymer coatings did not change the feel of any of the substrates, as determined by touching the substrates with bare hands before and after coating. Further, the coatings did not increase the weight of the substrates by more than 2%.

In order to increase the coating thickness and throughput, the total dwell time in a deposition zone and the stage temperature are the two variables requiring evaluation. A meandering loop design is used to increase the total dwell time experienced by a unit length of yarn as it passes through the deposition zones in each of the two polymer deposition chambers. Stage temperatures are more difficult since there will be a 2D distribution across the plate, however, thermocouples will be instrumented across the stage to compare the ‘local’ temperatures to the quality of coat. The local temperatures and corresponding regions of yarn can be used to correlate the effect of temperature with better resolution. Chamber pressures can also be used to tightly-control coating uniformity while increased throughput speed. Increased (>300 mTorr) chamber pressures then result in shorter mean free paths for the chemical species responsible for polymer chain growth in the chamber, which, in turn, afford greater surface coverage due to a higher frequency of surface-restricted reactions and suppression of line-of-sight deposition events.

By way of further explanation, in one embodiment, the poly(3,4-ethylenedioxythiophene) film formed from vapor phase polymerization using an iron salt is advantageous. In one embodiment, the dopant is uniformly distributed through the p-doped PEDOT film. In an embodiment, the poly(3,4-ethylenedioxythiophene) is uniformly doped having a dopant concentration of 10¹⁰ atoms per cm³ to 10²⁰ atoms per cm³ and a concentration variation of ±10³ atoms per cm³.

The 3,4-ethylenedioxythiophene has the structure of formula (1):

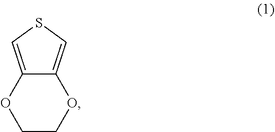

Upon polymerization, this has the structure of formula (2):

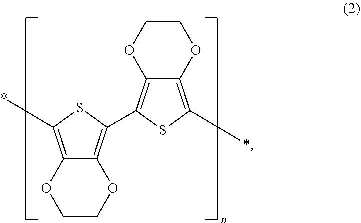

where “n” is the number of repeat units.

In an embodiment, n (the number of repeat units) may be greater than 20, preferably greater than 30, and more preferably greater than 40. In an embodiment, n is 20 to 10,000, preferably 50 to 9000, and more preferably 100 to 8500.

The iron salt may be any salt that can be vaporized (either by boiling or sublimation) at the reaction temperature. The iron salts may be divalent iron salts, trivalent iron salts, or a combination thereof. It is generally desirable for the iron salts to be trivalent iron salts. Examples of salts are iron (III) chloride, iron (III) bromide, iron (III) acetylacetonate, iron (III) sulfate, iron (III) acetate, iron(III) p-toluenesulfonate, or the like, or a combination thereof.

The amount of the 3,4-ethylenedioxythiophene vapor in the reactor is 20 to 80 volume percent, preferably 40 to 60 volume percent relative to the volume of the sum of the vapors of 3,4-ethylenedioxythiophene and the iron-salt. The amount of iron salt in the reactor is 20 to 80 volume percent, preferably 40 to 60 volume percent relative to the volume of the sum of the vapors of 3,4-ethylenedioxythiophene and the iron-salt. Other inert gases such as nitrogen and argon may be present in the reactor during the reaction.

The substrate upon which the film is disposed is an electrically insulating substrate. Electrically conducting substrates are those that have an electrical volume resistivity of less than or equal to 1×10¹¹ ohm-cm, while electrically conducting substrates are those that have an electrical volume resistivity of greater than 1×10¹¹ ohm-cm. The substrate may be in the form of a slab, a thin film or sheet having a thickness of several nanometers to several micrometers (e.g., 10 nanometers to 1000 micrometers), woven or non-woven fibers, yarns, a fabric, a gel, a pixel, a particle, or the like. The substrate may have a smooth surface (e.g., not deliberately textured) or may be textured.

The substrate may have a surface area of a few square millimeters to several thousands of square meters. In an embodiment, the surface of the substrate may have a surface area of 10 square nanometers to 1000 square meters, preferably 100 square nanometers to 100 square meters, preferably 1 square centimeter to 1 square meter.

In an embodiment, electrically insulating substrates may include ceramic substrates, or polymeric substrates. Ceramic substrates include metal oxides, metal carbides, metal nitrides, metal borides, metal silicides, metal oxycarbides, metal oxynitrides, metal boronitrides, metal carbonitrides, metal borocarbides, or the like, or a combination thereof. Examples of ceramics that may be used as the substrate include silicon dioxide, aluminum oxide, titanium dioxide, zirconium dioxide, cerium oxide, cadmium-oxide, titanium nitride, silicon nitride, aluminum nitride, titanium carbide, silicon carbide, titanium niobium carbide, stoichiometric silicon boride compounds (SiBn, where n=14, 15, 40, and so on) (e.g., silicon triboride, SiB3, silicon tetraboride, SiB4, silicon hexaboride, SiB6, or the like), or the like, or a combination thereof.

Organic polymers that are electrically insulating may also be used as the substrate and may be selected from a wide variety of thermoplastic polymers, blend of thermoplastic polymers, thermosetting polymers, or blends of thermoplastic polymers with thermosetting polymers. The organic polymer may also be a blend of polymers, copolymers, terpolymers, or combinations comprising at least one of the foregoing organic polymers. The organic polymer can also be an oligomer, a homopolymer, a copolymer, a block copolymer, an alternating block copolymer, a random polymer, a random copolymer, a random block copolymer, a graft copolymer, a star block copolymer, a dendrimer, a polyelectrolyte (polymers that have some repeat groups that contain electrolytes), a polyampholyte (a polyelectrolyte having both cationic and anionic repeat groups), an ionomer, or the like, or a combination comprising at last one of the foregoing organic polymers. The organic polymers have number average molecular weights greater than 10,000 grams per mole, preferably greater than 20,000 g/mole and more preferably greater than 50,000 g/mole.

Examples of the organic polymers are polyacetals, polyolefins, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyphthalides, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polyethylene terephthalate, polybutylene terephthalate, polyurethane, polytetrafluoroethylene, perfluoroelastomers, fluorinated ethylene propylene, perfluoroalkoxyethylene, polychlorotrifluoroethylene, polyvinylidene fluoride, polysiloxanes, or the like, or a combination thereof.

Examples of polyelectrolytes are polystyrene sulfonic acid, polyacrylic acid, pectin, carrageenan, alginates, carboxymethylcellulose, polyvinylpyrrolidone, or the like, or a combination thereof.

Examples of thermosetting polymers include epoxy polymers, unsaturated polyester polymers, polyimide polymers, bismaleimide polymers, bismaleimide triazine polymers, cyanate ester polymers, vinyl polymers, benzoxazine polymers, benzocyclobutene polymers, acrylics, alkyds, phenol-formaldehyde polymers, novolacs, resoles, melamine-formaldehyde polymers, urea-formaldehyde polymers, hydroxymethylfurans, isocyanates, diallyl phthalate, triallyl cyanurate, triallyl isocyanurate, unsaturated polyesterimides, or the like, or a combination thereof.

The polymers and/or ceramics may be in the form of films, fibers, single strands of fiber, woven and non-woven fibers, woven fabrics, slabs, or the like, or a combination thereof. The fibers may be treated with surface modification agents (e.g., silane coupling agents) to improve adhesion if desired.

In addition to fibers, fabrics, yarns and textiles, the present technique may be used to coat and/or encapsulate other substrates of interest for other applications. For instance, exemplary substrates are flat sheets, such as paper, foil, Tyvek, polymeric sheets including the polymer sheets listed above, porous, planar membranes, such as CELGARD®, or cylindrical or curved objects, such as monofilament NYLON® thread, single-ply silk thread, or monofilament fiberglass thread.

Suitable substrates further comprise plastics, metallized plastics, and metal foils. Exemplary substrates comprise greater than 80%, 70%, 60%, 50%, or 40% by atomic composition of metals. The contemplated thickness of the metal layers of exemplary metallized plastics (e.g., metallized plastics used in chip bags) comprise less than 100 nm coating of metals on a plastic substrate.

Optionally, substrates are pre-treated, e.g., by exposure to an inert gas plasma, to activate the surface and increase bonding between the substrate and the deposited material.

In one embodiment, liquid repellant substance is deposited on a substrate to which an electrically conductive polymer has already been deposited. In another embodiment, liquid repellant substance is deposited on a substrate to which no electrically conductive polymer has been applied. In a further embodiment, an electrically conductive polymer is deposited on the liquid repellant substance as described above. Optionally, a substrate to which liquid repellant polymer and electrically conductive polymer have been applied is coated with another layer of liquid repellant substance, e.g., sandwiching the electrically conductive polymer between layers of liquid repellant material. It should be appreciated that the coatings and layers disclosed herein need not be continuous and may or may not penetrate into the substrate and any previously applied coating materials.

In regard to liquid repellant substances, in one embodiment, the liquid repellent substance comprises polysiloxane. Examples of polysiloxanes include those resulting from the condensation of an alkylhalosiloxane, e.g., chlorosilane, dichlorosilane and/or trichlorosilane monomer with a diol and/or water as shown in Scheme 1. In some embodiments, the silane monomer and diol are vaporized and mixed at the time of coating. Exemplary chlorosilanes comprise one, two, or three alkyl groups bonded to each silicon atom. In further examples, halosilanes, such as bromo-, iodo-, and fluorosilanes are used as monomers. Exemplary alkyl groups (“R”) include methyl, ethyl, n-propyl, isopropyl, butyl, pentyl, hexyl, octyl or greater. It should be appreciated that alkyl groups may be branched or unbranched. Exemplary silanes comprise two alkyl groups that are the same (e.g., dimethyldichlorosilane, diethyldichlorosilane, diisopropyldichlorosilane), and in another embodiment, the silane includes two alkyl groups that are different (e.g., n-propylmethyldichlorosilane), As shown in Scheme 1, monomers may comprise dihalosilane (e.g., dichlorosilane) dimers, trimers, tetramers, pentamers, hexamers, heptamers, octomers and/or other oligomers.

Exemplary diols include alkyl diols having one to eight carbon atoms, which may be linear or branched (e.g., dihydroxymethane, ethyleneglycol, propylene glycol, etc.) as shown in Scheme 1. Examples of diols also comprise polyethylene glycols having between one and eight ethylene units. Use of polypropylene glycols is also contemplated.

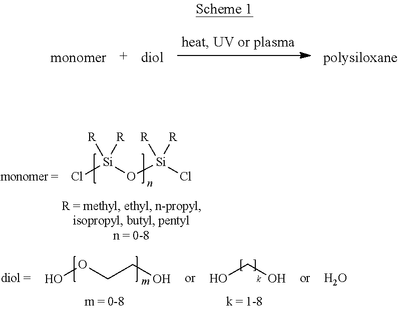

In some examples, a ratio of silane monomer to water and/or diol is about 1:10, about 1:9, about 1:8, about 1:7, about 1:6, about 1:5, about 1:4, about 1:3, about 1:2, about 1:1, or about 1:0.5 by volume.

Silane monomers react with water and/or a diol in one of the chambers disclosed herein (e.g., 110, 130, 210, 230, 410, 630A, 630B, 300A, 300B). In some embodiments, the formulation includes a disiloxane or trisiloxane monomer that is vaporized at the time of coating, and mixed at the time of coating with vapors of an aryl or diarylketone photoinitiator, and ultraviolet light of any wavelength lower than 400 nm. In other embodiments, the formulation includes a disiloxane or trisiloxane monomer that is vaporized at the time of coating and mixed at the time of coating with vapors of a diol, glycol and/or water in the presence of an electrically generated reactive ion plasma, such as an argon ion plasma. In all embodiments, a vacuum chamber with a plurality of ports needs to be used to mix and therefore induce a reaction between vapors of the silane or siloxane monomer and the co-reactant to form a polymer coating directly on the surface of any desired substrate. Substrates can comprise, paper, yarns, fibers and textiles that are woven, knit or nonwoven, plastics (e.g., polyethylene terephthalate (PET), polylactic acid (PLA), and polyethylene naphthalate (PEN), or any of the polymers disclosed herein and mixtures thereof), metallized plastics, and other composite materials. The reaction time, as defined as the total duration of time wherein the vapors of the monomers and various co-reactants are allowed to mix within the process chamber controls the thickness of the polysiloxane coating that is formed on the substrate surface. Exemplary reaction times include 1 minute, 2 minutes, 5 minutes, 7.5 minutes, 10 minutes, 15 minutes, 20 minutes, 25 minutes, 30 minutes, 35 minutes, 40 minutes, 45 minutes, 50 minutes, 55 minutes, 60 minutes, 65 minutes, 70 minutes, 75 minutes, 80 minutes, 85 minutes, 90 minutes, 95 minutes, 100 minutes, 105 minutes, 110 minutes, 115 minutes, or 120 minutes.

Polysiloxane coating thicknesses of less than one hundred micrometers result in liquid repellent textiles and yarns. The relative ratio of the siloxane monomer and co-reactant vapors can be controlled to increase or decrease the degree of polycondensation between polymer chains i.e., the crosslink density, and to increase or decrease the average polymer molecular weight of the polysiloxane coating. The crosslink density and polymer molecular weight can also be increased by introducing optional ultraviolet light or an electrically-generated reactive ion plasma into the process chamber at the same time as the monomer and co-reactant vapors are introduced into the chamber.

In further regard to liquid repellant substances, in one embodiment, the liquid repellent substance comprises poly(acrylate). In one embodiment, a method of coating a substrate with a liquid repellent polymer comprises vaporizing an acrylate, vaporizing a diacrylate, vaporizing an initiator, and initiating the polymerization of the acrylate and the diacrylate on a substrate.

Exemplary acrylates comprise fluoroalkyl acrylates, such as 3,3,4,4,5,5,6,6,7,7,8,8,8-tridecafluorooctyl acrylate, 3,3,4,4,5,5,6,6,7,7,8,8,8-tridecafluorooctyl methacrylate, and 3,3,4,4,5,5,6,6,7,7,8,8,9,9,10,10,10-heptadecafluorodecyl acrylate, and siloxyalkyl acrylates, such as 3-[Tris(trimethylsiloxy)silyl]propyl methacrylate. In one embodiment, the acrylate comprises 3,3,4,4,5,5,6,6,7,7,8,8,8-tridecafluorooctyl acrylate.

Exemplary diacrylates comprise alkyldiol diacrylates, such as 1,4-butanediol diacrylate, 1,4-butanediol dimethacrylate and 1,6-hexanediol diacrylate. In one embodiment, the diacrylate comprises 1,4-butanedioldiacrylate.

Polymerization may be initiated by heat and/or light. In one embodiment, the initiator comprises a photoinitiator, e.g., 2-hydroxy-2-methylpropiophenone.

FIG. 2 illustrates a system 200 for producing protected and/or electrically conductive 210 material that is rinsed in acid 220 and encapsulated with a protective coating 230 in which the material is continuously fed during processing. Coating chambers 210, 220, and 230 has been designed to maintain the appropriate vacuum notwithstanding the entrance of the substrate and exit of the protected material. In the embodiment of FIG. 2, first the substrate is fed through a coating chamber 210. Next, the substrate is continuously fed to a cleaning chamber 220. Next, the substrate is continuously fed to an encapsulating chamber 230.

In one example, the vacuum can be maintained using self-induced friction amplification, in which pulling the substrate in a given direction causes the opening to clamp tighter on the substrate to create a seal. A well-known example of this type of sealing is the popular finger trap toy or towing stock device. In another example, an external vacuum housing similar to a glove box could also be implemented to maintain vacuum while feeding substrate into the deposition chamber(s).

In yet another example, a single chamber could be used that includes all of the functions of the three chambers 210, 220, 230 e.g., in large scale factory production.

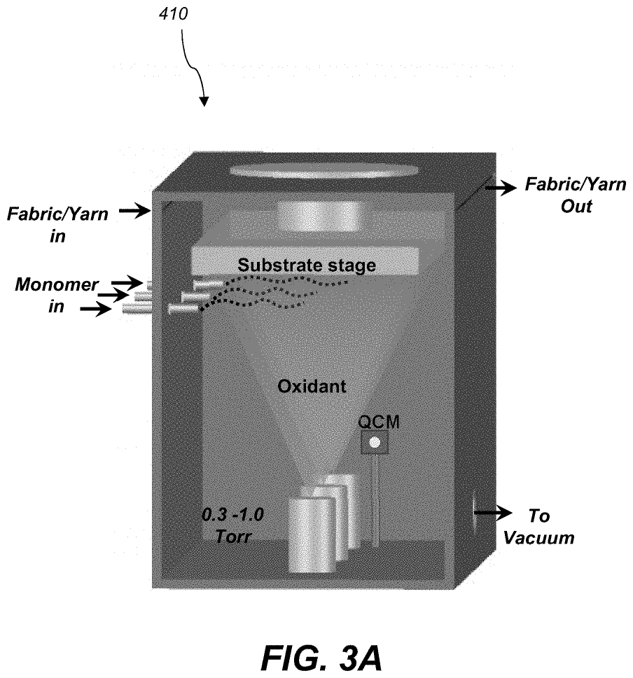

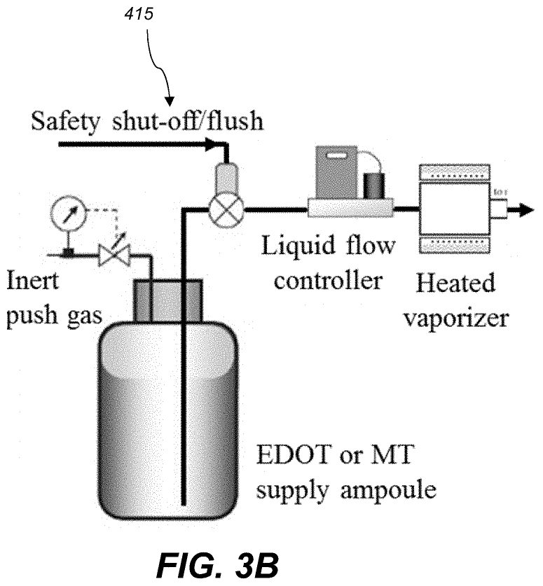

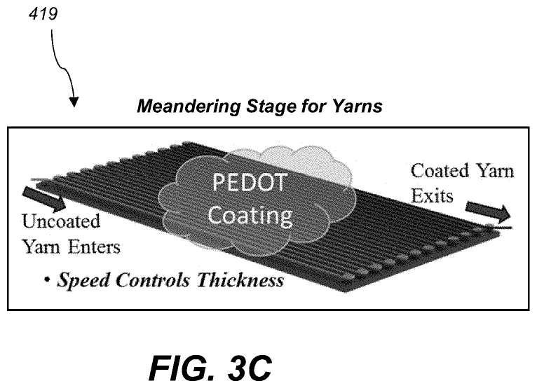

FIGS. 3A-3C depict further details of the coating chamber 410, e.g., chamber 110 (FIG. 1) or chamber 210 (FIG. 2). In the embodiment of FIG. 3A, the substrate 302 enters at the top of the chamber, contacts a heated substrate stage 304 placed above ports that introduce a monomer precursor for coating. A vacuum of 0.3-1.0 Torr is maintained using the techniques discussed above, and a QCM sensor 306 monitors the process.

In the embodiment of FIG. 3B, the monomer supply process is shown in additional detail. An EDOT supply ampoule 310 is carried using an inert gas supplied from an inlet 312 to the heated vaporizer 314. Additional components, including a safety shut-off 415 and a liquid flow controller 316 are used to ensure that the proper flow rate is maintained so that the material may be coated as the yarn is fed by the spooling mechanism discussed above.

In the embodiment of FIG. 3C, a meandering stage 419 designed for coating yarn 320 is shown. Meandering stage 419 includes a base 322 and a plurality of rotating guides 324 that are spaced along the left side and the right side of the base 322. When the meandering stage 419 is placed in chamber 410, as the yarn 320 is spooled, the yarn 320 to meander back and forth via the rotating guides 324 to ensure uniform coating and increased dwelling time. In one embodiment, separate meandering stages are used in each of the process chambers, i.e., the coating and encapsulation process chambers, and the speeds of spooling are matched and selected so that the coating process and encapsulation process leads to uniformly encapsulated and coated yarn, as the yarn 320 enters the meandering stage 419 at location 326 and exits the meandering stage at location 328. Applicant has discovered that the combination of a meandering stage with vapor deposition advantageously leads to a uniform coating.

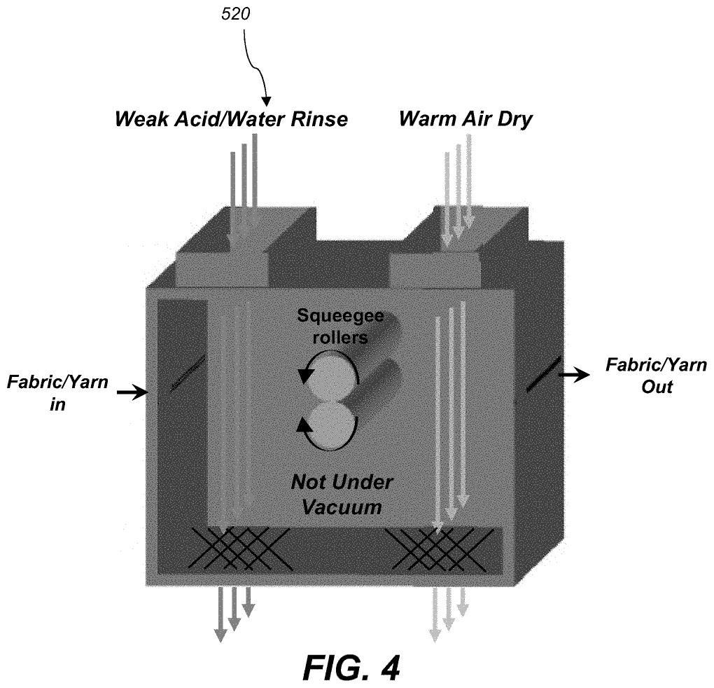

FIG. 4 depicts further details of the cleaning chamber 520, which may be used as the cleaning chambers 120 (FIG. 1) or 220 (FIG. 2). To remove excess oxidant and achieve a stably-doped conductive polymer, the substrate enters at port 424 and exits at port 426, and is rinsed using a monoprotic acid such as 0.1 moles per litre hydrochloric acid (HCl) delivered from source 420. As depicted in FIG. 4, the acid can be spray misted via source 420 through the textile or yarn. The textile or yarn can be dried by feeding through a set of squeegee rollers 428 followed by warm air blowing through it from dryer 422. The cleaning stage need not be carried out under vacuum, so in a separate chamber embodiment of the overall system can be used without vacuum. In a unified embodiment in which coating, cleaning, and encapsulation are all carried out in a single chamber, the cleaning process can also proceed under vacuum, with adjustments to how the rinse is removed via the outlet 430.

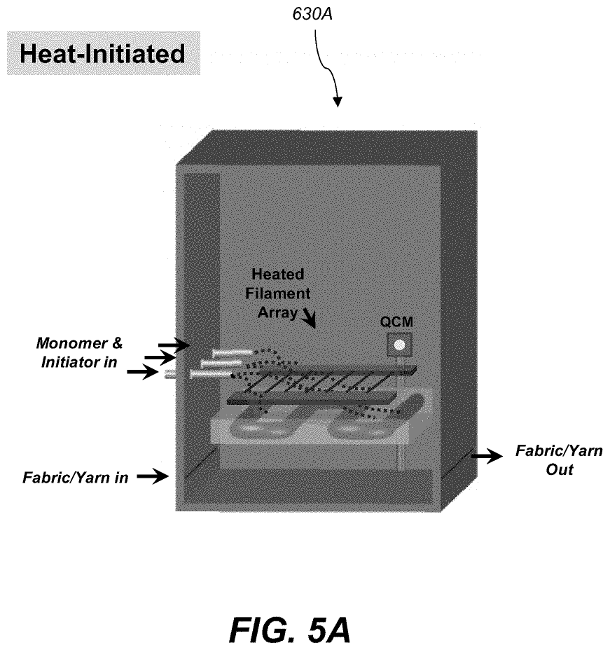

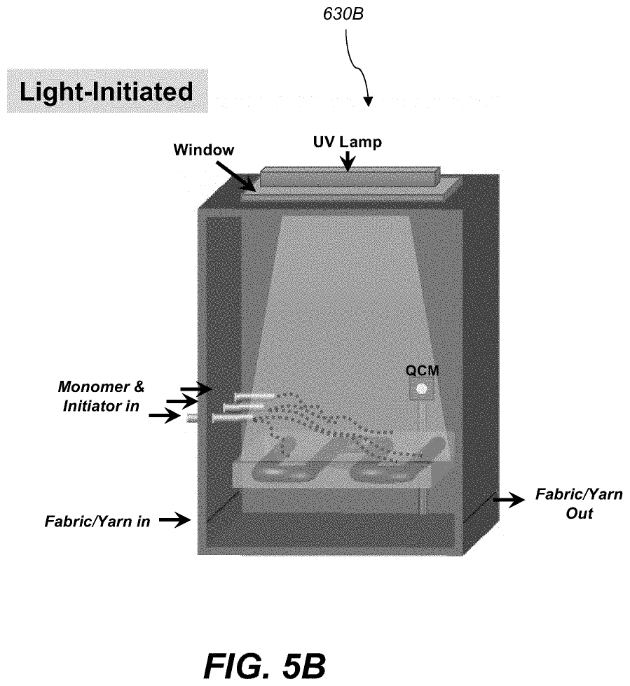

FIGS. 5A & 5B depicts further details of a chamber 630A which may be used interchangeably with any of the chambers described above, e.g., chambers 130 (FIG. 1) or 230 (FIG. 2). In the heat-initiated embodiment of FIG. 5A, the monomer and initiator are fed into the chamber 630B via inlet 530 and heated by a heated filament array 420, which includes a metal structure 421 that distributes heat for vapor phase polymerization 535 (which is depicted in an exaggerated manner as a mist of particles). The yarn enters at input 532 and exits at output 538 and is coated with the in the manner described above. In one embodiment, a quartz crystal microbalance (QCM) sensor 534 is used to determine that the correct thickness has been achieved.

In the embodiment of FIG. 5B, instead of heating the monomer and initiator, a UV lamp 540 is placed at the top of chamber 630B, and the UV light (wavelength <400 nm) 544 shines through the window 542 at the top of chamber 630B and interacts with the monomer and initiator for vapor phase polymerization 546.

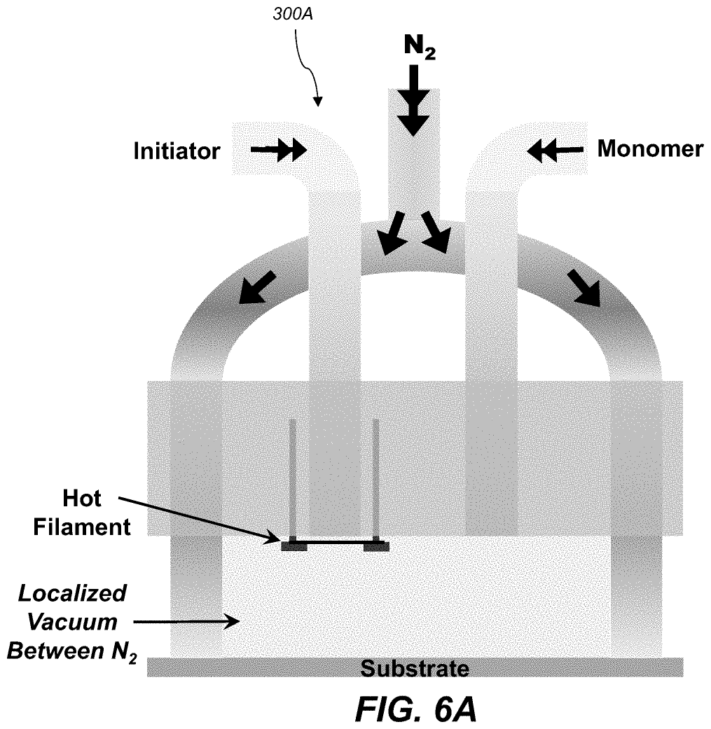

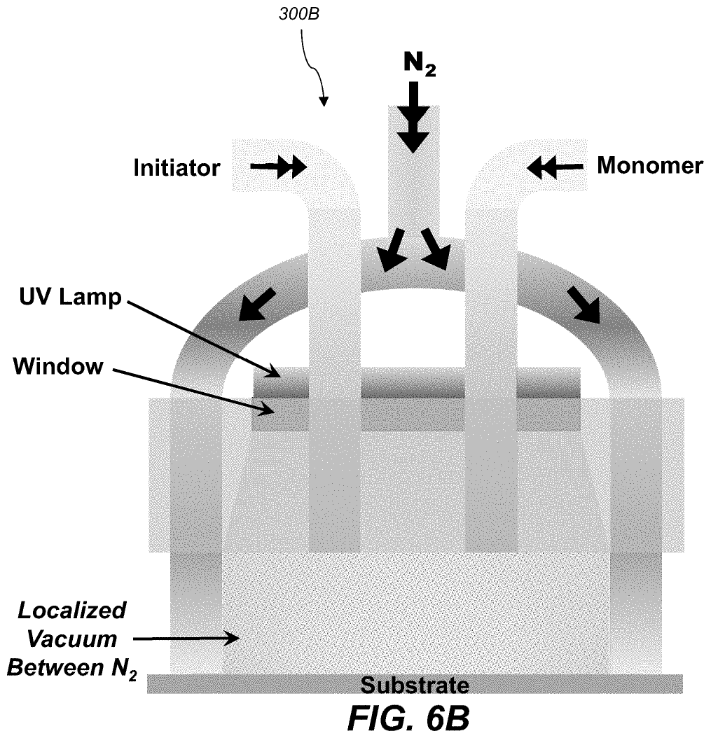

FIG. 6A illustrates a print head 300A for producing electrically conductive patterns onto any substrate 612, such as a flat or smooth plastic, paper, transparent conducting oxide or metal oxide surface, or nonwoven, prewoven or knit fabric surface, in which EDOT monomer and solid oxidant, such as Fe(III) salts or Copper(II) salts, vapors are sprayed to form PEDOT directly on the surface. The print head 300A includes an initiator inlet 602 and a monomer inlet 604 for the aforementioned oxidant and monomer, or any other variation disclosed herein, as well as a carrier gas inlet 606, and a manifold 608 that distributes the gases to an interior of the print head where the polymerization 610 begins prior to deposition on the substrate 612. This print head is capable of printing complexly patterned conductive polymer lines and shapes, i.e. the shape of a hand, and it can print in a resolution as small as 10 microns. The body of the print head is in the shape of a cylinder. It is made of alumina or another thermally stable ceramic that has feedthroughs for resistively heated filaments 620 such as tungsten and thermocouples for controlling power delivery and maintaining temperature. The heated filament coils within the body of the print head to heat the bottom of the EDOT reservoir, sidewalls, and tip of the funnel that delivers the oxidant. The EDOT monomer is held in a reservoir, and it can feature a carrier gas line to help deliver EDOT vapor to the substrate. The oxidant is contained in a reservoir above the funnel section of the ceramic body, and an auger screw can be incorporated to control the delivery of oxidant to the heated funnel section, which then leads to the substrate. The hottest part of the funnel section is near the tip, and this is achieved by having more wraps of the heated filament closer to the tip. The resistively heated filaments will heat the body of the ceramic causing the EDOT monomer to vaporize and the oxidant to sublimate. The two vapors will then flow out and down, and they will interact above the surface to coat it in PEDOT. The height between the surface of the substrate and the tip of the print head can be 0.1-1.0 mm.

In the embodiment of FIG. 6A, system 300A is a heat initiated print head for printing an encapsulating polymer onto any substrate, e.g., flat or smooth plastic, paper, transparent conducting oxide or metal oxide surface, or nonwoven, prewoven or knit fabric surface. This print head is an inkjet printer head, e.g., less than 10 cm wide and located approximately 1-10 mm in distance from the substrate surface. The printer head is equipped with nitrogen gas jets, monomer feed, and initiator feed. Nitrogen gas is used to help carry the monomer and initiator vapors out of their ampules, and the monomer and initiator ampules can have a similar setup as FIG. 3B. The nitrogen gas jets creates a vacuum space, such that the chemical reaction occurs in a localized vacuum area on the substrate. The monomer and initiator vapors are mixed before flowing past the nichrome filament, and they are flowed in this localized vacuum area because the presence of oxygen inhibits the polymerization. The vaporized monomer/initiator mix will flow past a resistively heated nichrome filament that is heated between 150-400° C. before reaching the substrate to initiate radicals that in turn radicalize the monomer so it can polymerize the encapsulating material on the substrate surface. Openings for monomer/initiator are in the range of e.g., 10 to 100 micrometers in diameter, in one embodiment.

With respect to the print head embodiment described above, conventional print heads are known for printing using liquid inks. For example, conventional inkjet printer propel a liquid ink onto paper in order to produce a pattern using either heat, pressure, or a combination thereof in a conventional manner that is well understood and well known to the ordinary artisan in the field. But conventional print heads are incapable of delivering two components that are supposed to react, and even further lack the concept of having an initiation means, such as heat or light, to cause such as reaction. Conventional print heads are designed for speed, and printing onto flat paper only, have no facility for initiating chemical reactions, and thus cannot be used to create an electrically conductive polymer coating as described herein. A person of ordinary skill in the art will understand that conventional ink jet printers include both one or more print heads and a control mechanism that allows the print heads, which include may include numerous output nozzles for different color inks, to move back and forth along a sheet of paper in order to print the required pattern. Such control mechanisms may be used with the present technique so that the presently described innovative print heads may move back and forth over any of the types of substrates described herein to form an electrically conductive and encapsulated coating on those substrates.

Advantageously, the presently disclosed vapor deposition print head includes light initiated or heat initiated polymerization of a monomer and an initiator so that an electrically conductive material such as PEDOT can be conformally deposited on a substrate such as a yarn, fiber, fabric or textile. The print head can also include another nozzle from which an encapsulating material is delivered. The control mechanism can then time the delivery of the materials so that as the print head moves above the substrate, a fully encapsulated, electrically conductive polymer such as PEDOT is delivered to the substrate in whatever pattern is desired. Because the vapor phase polymerization can occur within a short distance such as a few centimeters, the result is a substrate that is conformally coated and encapsulated with the conductive polymer.

In the embodiment of FIG. 6B, system 300B is light initiated. The print head of system 300B would function similarly as 300A (see common reference numbers as discussed above), but instead of generating radicals using heated nichrome wires of filament 620, it will generate radicals using UV light (wavelength <400 nm) introduced from UV lamp 540 via window 542. In this case, the nichrome filament 620 is not needed. The UV light will flood the space through which the monomer and initiator vapors will travel, the distance between tip of the print head and substrate, and the substrate. The substrate-facing part of the print head would be made up of a quartz glass such as to allow UV light (wavelength <400 nm) through.

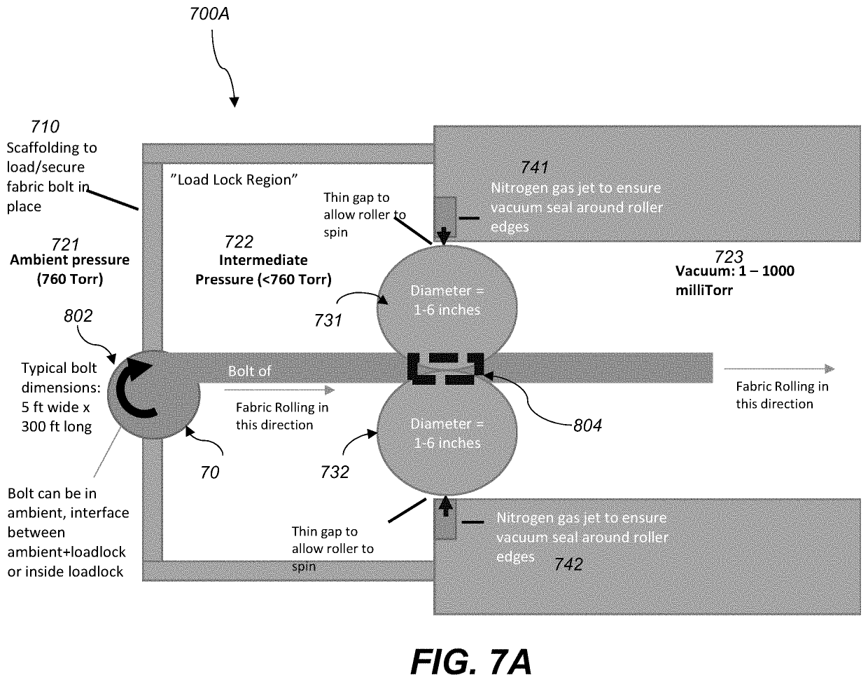

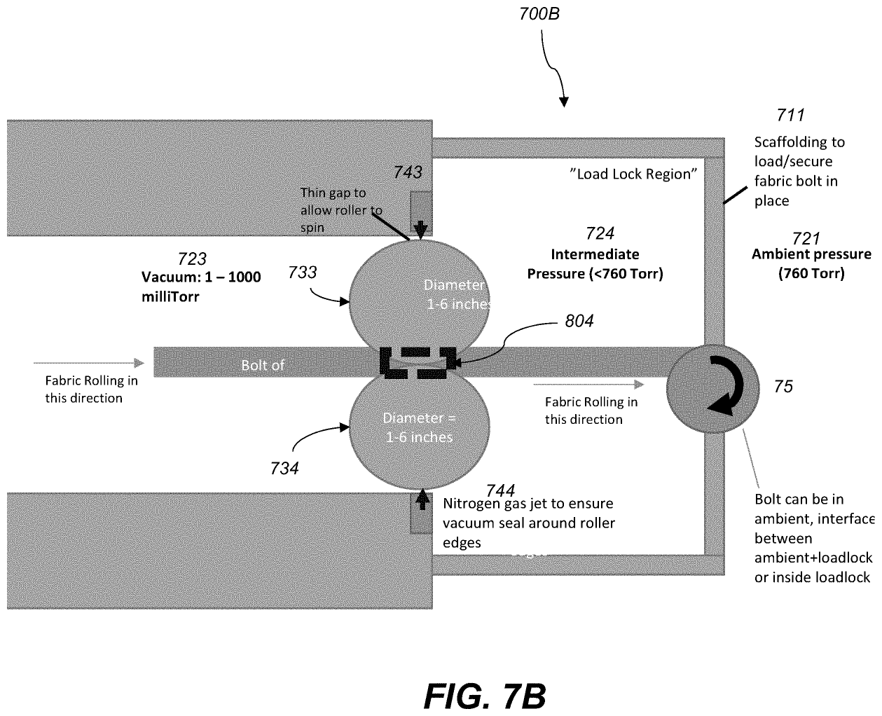

In some embodiments, the process chambers (e.g., 110, 130, 210, 230, 410, 630A, 630B) further comprise entry and/or exit load lock chambers as shown in FIGS. 7A & 7B. During operation, load lock chambers are maintained at a pressure between the external, ambient pressure (about 760 Torr) and the reduced pressure in the process chamber (1-1,000 milliTorr). Maintaining three or more discrete pressure regions (ambient pressure region 721, one or more intermediate pressure (also referred to as a “Load Lock Region”) 722 and 724, and a vacuum region₇₂₃) while substrate is unrolled and fed into the process chamber and/or after the substrate is removed from the process chamber (and in some embodiments rerolled). Advantageously, entry and/or exit load lock chambers allow for continuous, roll-to-roll feeding of a single sheet of substrate, unfurled from a bolt, into a process chamber under vacuum, and the associated reverse process where a single sheet of substrate is rolled into a bolt under ambient upon exiting a vacuum chamber.

One embodiment of entry load lock chamber 700A is shown in FIG. 7A. A segment or bolt of substrate 70 may be located outside, inside, or partially inside and partially outside of entry load lock chamber 700A. In one embodiment, the segment or bolt of substrate 70 is located outside entry load lock chamber 700A to facilitate changing bolt of substrate 70 while maintaining the vacuum in entry load lock chamber 700A and in the connected process chamber. Exemplary substrates are about 300 feet long and 5 feet wide.

In one embodiment a spool 802 of substrate 70 is secured by a support or scaffolding 710. The substrate 70 enters vacuum region 723 through a load lock-vacuum interface, space or zone 804 located between by compressing rollers 731 and 732, which are supported by a frame or support (not shown). Depending on the embodiment, the compressing rollers 731, 732 can be driver rollers that are electromechanically powered to rotate. In an embodiment, the compressing rollers 731 and 732 are configured to freely rotate. The system has a plurality of gas directors 741, 742 associated with the compressing rollers 731, 732, respectively. To allow or cause the compressing rollers 731, 732 to rotate while maintaining the vacuum in the vacuum region/process chamber, each of the gas directors 741, 742 outputs a jet of nitrogen gas, which is streamed at high velocity over a gap between the associated roller and the edges of the vacuum region/process chamber. In an embodiment, gas director 741 generates a gas stream that flows fully or partially around the circumference of compressing roller 731, and gas director 742 generates a gas stream that flows fully or partially around the circumference of compressing roller 732. Without wishing to be bound by a particular hypothesis, the gas streams generate a pressure reduction effect, such as the Bernoulli effect. In an embodiment, the Bernoulli effect is used to maintain an intermediate vacuum (between about 760 Torr and about 1 Torr) between ambient pressure region 721 and vacuum region 723. In one embodiment, an ultrahigh nitrogen gas flow (“nitrogen knife”) 741 and 742 pushes out ambient gases and maintains a pressure differential between the ambient and the intermediate pressure regions. In one embodiment, the nitrogen gas jets/knives 741 and 742 also apply pressure to rollers 731 and 732 increasing the contact between the rollers and the substrate 70 at the load lock-vacuum interface 804.

One embodiment of exit load lock chamber 700B is shown in FIG. 7B. The substrate 70 exits vacuum region 723 through a load lock-vacuum interface 804 between compressing rollers 733 and 734, which are supported by a frame or support (not shown). Depending on the embodiment, the compressing rollers 733 and 734 can be driver rollers that are electromechanically powered to rotate. In an embodiment, the compressing rollers 733 and 734 are configured to freely rotate. As in entry load lock chamber 700A, the system has a plurality of gas directors 743 and 744 associated with the compressing rollers 733 and 734, respectively. To allow or cause the compressing rollers 733, 734 to rotate while maintaining the vacuum in the vacuum region/process chamber, each of the gas directors 743, 744 outputs a jet of nitrogen gas, which is streamed at high velocity over a gap between the associated roller and the edges of the vacuum region/process chamber, thereby maintaining an intermediate vacuum (between about 760 Torr and about 1 Torr) between ambient pressure region 721 and vacuum region 723. In an embodiment, gas director 743 generates a gas stream that flows fully or partially around the circumference of compressing roller 733, and gas director 744 generates a gas stream that flows fully or partially around the circumference of compressing roller 734. In one embodiment, an ultrahigh nitrogen gas flow (“nitrogen knife”) 743 and 744 pushes out ambient gases and maintains a pressure differential between the ambient and the intermediate pressure regions. In one embodiment, the nitrogen gas jets/knives 743 and 744 also apply pressure to rollers 733 and 734 increasing the contact between the rollers and the substrate 70 at the load lock-vacuum interface.

Optionally, in some embodiments, the substrate 70 is wound on spool 75, which may be located outside, inside, or partially inside and partially outside of exit load lock chamber 700B. In one embodiment, the bolt of substrate 70 on spool 75 is located outside entry load lock chamber 700B to facilitate changing spool 75 while maintaining the vacuum in exit load lock chamber 700B and in the connected process chamber. In one embodiment spool 75 is secured by scaffolding 711.

In some embodiments, rollers 731, 732, 733, and 734 comprise silicone and separate the intermediate region from the vacuum region. Exemplary rollers have diameters of about 0.5 inches to about 1 inch, about 1 inch to about 1.5 inches, about 1.5 inches to about 2 inches, about 2 inches to about 2.5 inches, about 2.5 inches to about 3 inches, about 3 inches to about 3.5 inches, about 3.5 inches to about 4 inches, about 4 inches to about 4.5 inches, about 4.5 inches to about 5 inches, about 5 inches to about 5.5 inches, about 5.5 inches to about 6 inches, about 6 inches to about 6.5 inches, about 6.5 inches to about 7 inches, about 7 inches to about 7.5 inches, about 7.5 inches to about 8 inches, about 8 inches to about 8.5 inches, about 8.5 inches to about 9 inches, about 9 inches to about 9.5 inches, about 9.5 inches to about 10 inches, or larger.

In some embodiments, the vacuum region/process chamber (e.g., 110, 130, 210, 230, 410, 630A, 630B) is connected to a mechanical pump that maintains the vacuum chamber at between 1-1000 millitorr and the silicone rollers allow this vacuum level to be maintained by prevent gas bleed-through from the intermediate region to the vacuum region.

### EXAMPLES

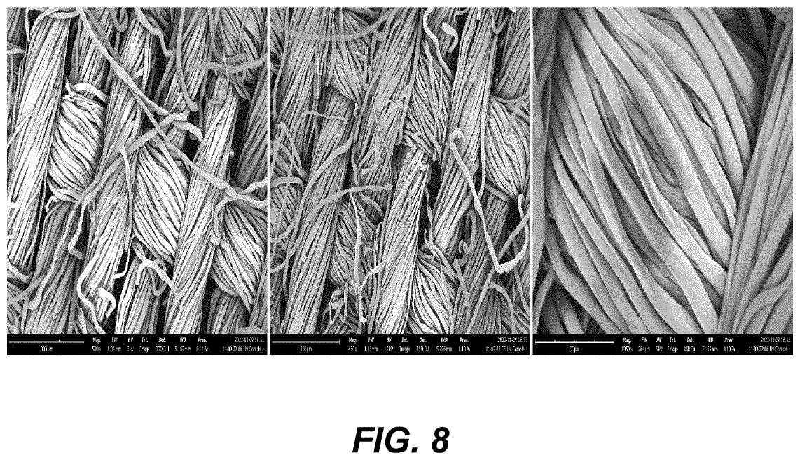

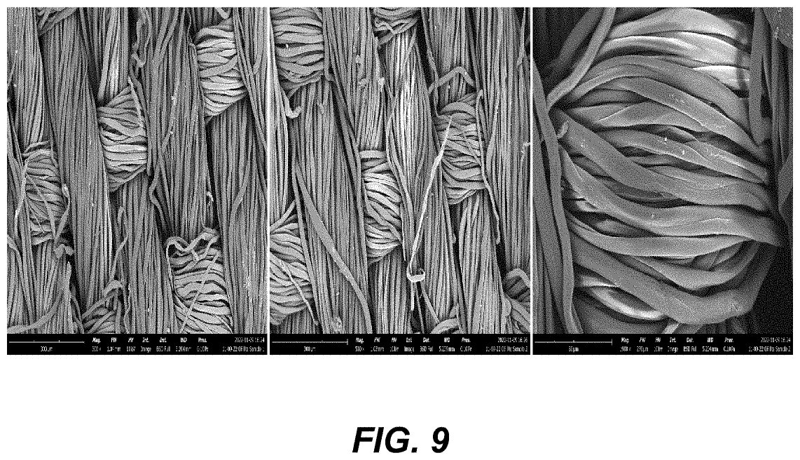

The following table provides exemplary embodiments of substrates coated with water and/or oil repellant substances produced using the systems and methods described herein. Water repellency was tested using ISO 4920:2012 Textile fabrics—Determination of resistance to surface wetting (spray test). “Yes” corresponds to coatings that repel water for 8 hours or more. Oil Repellency was measured using ISO 14419:2010 Textiles—Oil repellency—Hydrocarbon resistance test, where ISO 0 corresponds to no oil repellency and ISO 8 corresponds to maximum oil repellency. Additionally, the exceptional conformality of the coating of Sample Nos. 20 and 21 are illustrated in the SEM images presented in FIGS. 8 and 9, respectively.

| | | | | Water | Oil |
|---|---|---|---|---|---|
| No. | Substrate | Reagents | Observations | Repellent? | Repellent? |
| 1 | Muslin | 1 mL n- | Pressure | Repels for a | No |
| | | propylmethyldichlorosilane | abnormally high. | very long | |
| | | with 2 mL water | Pump closed. 1 | time with | |
| | | | hour deposition. | very slow | |
| | | | Set point c at 20 | absorption | |
| | | | minutes. Water in | | |
| | | | graduated cylinder | | |
| | | | inside chamber. | | |
| 2 | Muslin | 1 mL n- | Pressure still high. | Water begins | No |
| | | propylmethyldichlorosilane | Set point c for | absorbing | |
| | | with 4 mL water | whole run. 1 hour | immediately, | |
| | | | deposition. Water | faster on one | |
| | | | in graduated | side (non- | |
| | | | cylinder inside | uniform). | |
| | | | chamber. | | |
| 3 | Muslin | 1 mL n- | Pressure still high. | Repels for a | No |
| | | propylmethyldichlorosilane | Pump closed for | very long | |
| | | with 4 mL water | whole run (true | time with | |
| | | | for all future | very slow | |
| | | | runs). Water in | absorption | |
| | | | separate ampule to | | |
| | | | be introduced at | | |
| | | | appropriate | | |
| | | | pressure (true for | | |
| | | | all future runs). 1 | | |
| | | | hour deposition. | | |
| 4 | Muslin | 1 mL n- | Pressure still high. | Non-uniform. | No |
| | | propylmethyldichlorosilane | Pump closed. 1 | Half bad half | |
| | | with 2 mL water and 2 mL | hour deposition. | decent. | |
| | | antifreeze | | | |
| 5 | Muslin | 1 mL n- | Pressure still high. | Repelled | No |
| | | propylmethyldichlorosilane | Pump closed. 30 | for >3 hours | |
| | | with 4 mL water | minute deposition. | before finally | |
| | | | | soaking | |
| | | | | through | |
| 6 | Muslin | 1 mL n- | Pressure still high. | Repels for a | No |
| | | propylmethyldichlorosilane | Pump closed. 30 | very long | |
| | | with 2 mL water and 2 mL | minute deposition. | time with | |
| | | antifreeze | | very slow | |
| | | | | absorption | |
| 7 | Muslin | 1 mL n- | Pressure still high. | Repels for a | No |
| | | propylmethyldichlorosilane | Pump closed. 15 | very long | |
| | | with 4 mL water | minute deposition. | time with | |
| | | | Replaced leaky o- | very slow | |
| | | | ring, did not affect | absorption | |
| | | | pressure too | | |
| | | | much. | | |
| 8 | Muslin | 1 mL n- | Pressure still high. | Repels for a | No |
| | | propylmethyldichlorosilane | Pump closed. 7.5 | very long | |
| | | with 4 mL water | minute deposition. | time with | |
| | | | | very slow | |
| | | | | absorption | |
| 9 | Muslin | 1 mL 1,7-dichloro- | New reagent. | Water | No |
| | | octamethyltetrasiloxane and 4 | Pressure still high. | immediately | |
| | | mL water | Pump closed. 5 | begins to | |
| | | | minute deposition. | absorb | |
| 10 | Muslin | 1 mL 1,7-dichloro- | Using prototype | Very poorly | No |
| | | octamethyltetrasiloxane and 4 | perforated stage | | |
| | | mL water | (true for all future | | |
| | | | runs). Pressure | | |
| | | | still high. Pump | | |
| | | | closed. 5 minute | | |
| | | | deposition. | | |
| 11 | Muslin | 1 mL 1,3- | New reagent. | Near perfect | No |
| | | dichlorotetramethyldisiloxane | Pressure still high. | water | |
| | | and 4 mL water | Pump closed. 5 | repellency at | |
| | | | minute deposition. | first. Then | |
| | | | | very slowly | |
| | | | | absorbs. | |
| 12 | Loose | 0.5 mL 1,3- | New substrate. | Good water | No |
| | weave | dichlorotetramethyldisiloxane | Halved siloxane. | repellency for | |
| | cotton | and 4 mL water | Pressure still high. | a short period | |
| | gauze | | Pump closed. 1 | (could be a | |
| | | | minute deposition. | symptom of | |
| | | | | loose weave | |
| | | | | fabric) | |
| 13 | Loose | 0.5 mL 1,3- | Pressure still high. | Good water | No |
| | weave | dichlorotetramethyldisiloxane | Pump closed. 10 | repellency for | |
| | cotton | and 4 mL water | minute deposition. | a short period | |
| | gauze | | Halved siloxane. | (could be a | |
| | | | Pressure increased | symptom of | |
| | | | less and more | loose weave | |
| | | | water left over at | fabric) | |
| | | | the end. | | |
| 14 | Loose | 1 mL 1,3- | Gently heated | N/A | N/A |
| | weave | dichlorotetramethyldisiloxane | water (true for all | | |
| | cotton | and 4 mL water | future runs). | | |
| | gauze | | Pressure still high. | | |
| | | | Pump closed. 1 | | |
| | | | minute deposition | | |
| | | | starting halfway | | |
| | | | through siloxane | | |
| | | | heating. 80% of | | |
| | | | siloxane did not | | |
| | | | evaporate (need to | | |
| | | | let siloxane reach | | |
| | | | peak T). | | |
| 15 | Loose | 1 mL 1,3- | Reusing substrate | Good water | No |
| | weave | dichlorotetramethyldisiloxane | from previous run | repellency for | |
| | cotton | and 4 mL water | after testing that | a short period | |
| | gauze | | the previous run | (could be a | |
| | | | did not bestow | symptom of | |
| | | | water repellency. | loose weave | |
| | | | Pressure still high. | fabric) | |
| | | | Pump closed. 1 | | |
| | | | minute deposition | | |
| | | | from when peak T | | |
| | | | was reached. 30% | | |
| | | | siloxane left over. | | |
| 16 | Loose | 1 mL 1,3- | Pressure still high. | Good water | No |
| | weave | dichlorotetramethyldisiloxane | Pump closed. 5 | repellency for | |
| | cotton | and 4 mL water | minute deposition. | a short period | |
| | gauze | | | (could be a | |
| | | | | symptom of | |
| | | | | loose weave | |
| | | | | fabric) | |
| 17 | Polyester | 0.5 mL 1,3- | New substrate. | No | No |
| | | dichlorotetramethyldisiloxane | Halved siloxane. | | |
| | | and 4 mL water | Pressure still high. | | |
| | | | Pump closed. 10 | | |
| | | | minute deposition. | | |
| 18 | Polyester | 1 mL 1,3- | Pressure still high. | No | No |
| | | dichlorotetramethyldisiloxane | Pump closed. 1 | | |
| | | and 4 mL water | minute deposition | | |
| | | | (after reaching | | |
| | | | peak T). 20% | | |
| | | | siloxane left over. | | |
| 19 | Polyester | 1 mL 1,3- | Pressure still high. | For a few | No |
| | | dichlorotetramethyldisiloxane | Pump closed. 5 | seconds | |
| | | and 4 mL water | minute deposition. | | |
| 20 | Loose | 2 mL 1,4-butanediol | Pump closed. 30 | Yes | Yes |
| | weave | diacrylate, 0.5 mL | minute deposition. | | ISO 6.5 |
| | cotton | 3,3,4,4,5,5,6,6,7,7,8,8,8- | | | |
| | gauze | tridecafluorooctyl acrylate | | | |
| | | and 3 mL 2-hydroxy-2- | | | |
| | | methylpropiophenone | | | |
| 21 | Muslin | 2 mL 1,4- | Pump closed. 30 | Yes | Yes |
| | | butanedioldiacrylate, 0.5 mL | minute deposition. | | ISO 6 |
| | | 3,3,4,4,5,5,6,6,7,7,8,8,8- | | | |
| | | tridecafluorooctyl acrylate | | | |
| | | and 3 mL 2-hydroxy-2- | | | |
| | | methylpropiophenone | | | |
| 22 | Polyester | 2 mL 1,4- | Pump closed. 30 | Yes | — |
| | | butanedioldiacrylate, 0.5 mL | minute deposition. | | |
| | | 3,3,4,4,5,5,6,6,7,7,8,8,8- | | | |
| | | fridecafluorooctyl acrylate | | | |
| | | and 3 mL 2-hydroxy-2- | | | |
| | | methylpropiophenone | | | |

Many examples of the utility of the present disclosure have been contemplated by the inventors, including heated gloves, hats, and other clothing, printed circuits that are embedded onto clothing to form wearable devices, etc. Various other applications of the present disclosure have been contemplated, including wearables that provide heat to a user, monitor the users health by measuring electric signals and temperatures, allow for mounting of other components such as blood pressure or oxygen sensors, etc.

Therefore, and as discussed above, generally stated, provided herein are a variety of techniques for coating electrically conductive polymer onto substrates including flat or smooth plastic, paper, transparent conducting oxide or metal oxide surface, or nonwoven, prewoven or knit fabric surface that is encapsulated with an insulating material. The various components FIGS. 1-6B can be rearranged or combined in different ways to construct systems for producing the material. For instance, any of the chambers 110, 120, 130, 210, 220, 230, 410, 520, 630A, or 630B can be mixed and matched to provide a system in accordance with the present disclosure. In addition, the process details discussed with respect to the chamber based embodiments are also applicable to the printer/spray head embodiments 300A, 300B and 300C. In addition, certain well-known details have only been touched upon, such as the use of an inert carrier gas to carry the chemicals through the process chamber, the use of vacuum pumps to maintain a vacuum, the use of motors and other details of the spooling mechanism, etc., that a person of ordinary skill in the art would understand.

The fact that one or more specific embodiments for coating, cleaning and encapsulating have been used to illustrate the concepts of the present technique are not meant to limit the disclosure in any manner. Indeed, as noted above, the concepts disclosed herein are not limited to the disclosed substrates (e.g., textiles, yarns, fibers or fabrics). For example, many other applications of the different processes described herein have been envisaged by the inventors and are included within the scope of this disclosure. The presentation of a specific set of claims herein is not meant to limit scope, but is only done to illustrate some of the example embodiments which are covered by this disclosure. For example, the techniques described herein may be scaled in size from a large factory embodiment measuring many yards in each direction down to a smaller table-top apparatuses that are only a few feet in size. In addition to fiber, fabric, and yarn embodiments, the present disclosure could be used for producing circuits that are printed on any of the substrates identified above, and the coating and encapsulation process can be used to form the conductive lines of the circuit. By adding other electrical or semiconductor elements in a manner known in the art, the end product would be a wearable or non-wearable circuit or electronic device that could be conformed to any surface or configuration, providing great advantages compared to flat circuit boards presently used in the field.

1. A system for producing liquid repellent materials comprising:
a first load lock chamber comprising an inlet for a substrate and coupled to an inlet of a process chamber;
first and second rollers disposed between the first load lock chamber and the process chamber at the inlet of the process chamber; and
first and second inert gas outlets configured to stream an inert gas against a length of a surface of each of the first and second rollers, respectively.

2. The system of claim 1 further comprising a first spooling mechanism that stores the substrate and is disposed outside, inside, or partially outside and partially inside the load lock chamber, and is configured to unspool the substrate as the substrate enters the process chamber.

3. The system of claim 1 further comprising a second load lock chamber that comprises:
third and fourth rollers disposed between the process chamber and the second load lock chamber at the inlet of the process chamber;
third and fourth inert gas outlets configured to stream an inert gas against a length of a surface of each of the third and fourth rollers, respectively; and
an outlet for the substrate.

4. The system of claim 3 further comprising a second spooling mechanism that accepts the substrate from the process chamber and is configured to spool the substrate.

5-23. (canceled)
